(19) United States
(12) Patent Application Publication
(10) Pub. No.: US 2020/0279760 A1
(43) Pub. Date: Sep. 3, 2020

(54) ETCHING DEVICE

(71) Applicant: TOYOTA JIDOSHA KABUSHIKI KAISHA, Toyota-shi (JP)

(72) Inventors: Daisuke SUGIZAKI, Nagakute-shi (JP); Eiko Ishii, Nagakute-shi (JP); Kenji Nakashima, Nagakute-shi (JP); Kunio Akedo, Nagakute-shi (JP); Koji Noda, Nagakute-shi (JP)

(73) Assignee: TOYOTA JIDOSHA KABUSHIKI KAISHA, Toyota-shi (JP)

(21) Appl. No.: 16/791,466

(22) Filed: Feb. 14, 2020

(30) Foreign Application Priority Data
Mar. 1, 2019 (JP) 2019-037747

(51) Int. Cl. H01L 21/67

(52) U.S. Cl. CPC H01L 21/67086

(57) ABSTRACT

An etching device may include a reservoir storing an etchant, a support member configured to rotatably support the semiconductor wafer in a state where a first surface of the semiconductor wafer is immersed in the etchant, a light source configured to emit light to the first surface of the semiconductor wafer, a counter electrode disposed in the reservoir and disposed between the support member and the light source, and a power source configured to apply a voltage between the semiconductor wafer and the counter electrode. When the light source emits light, a lighted area by the light and a shadow of the counter electrode may be projected onto the first surface of the semiconductor wafer, and when the semiconductor wafer is rotated by the support member, at least a part of the first surface may pass both the lighted area and the shadow.

### CROSS-REFERENCE TO RELATED APPLICATION

This application claims priority to Japanese Patent Application No. 2019-037747, filed on Mar. 1, 2019, the entire contents of which are incorporated herein by reference.

### TECHNICAL FIELD

The technology disclosed herein relates to an etching device. The technology disclosed herein particularly relates to an etching device configured to photoelectrochemically etch a semiconductor wafer.

### BACKGROUND

Japanese Patent Application Publication No. 2017-212262 describes an etching device configured to etch a semiconductor wafer by photoelectrochemical etching. This etching device includes a reservoir storing an etchant, a mount configured to allow the semiconductor wafer to be mounted thereon in a state where the semiconductor wafer is immersed in the etchant, a light source configured to emit light to a surface of the semiconductor wafer mounted on the mount, a counter electrode disposed in the reservoir, and a power source configured to apply a voltage between the mounted semiconductor wafer and the counter electrode.

When the semiconductor wafer is etched, the light is emitted to the semiconductor wafer in a state where a voltage is applied between the semiconductor wafer and the counter electrode. Due to this, electrons in a valence band of the semiconductor wafer are excited and move to a conduction band across a band gap. The excited electrons move from the semiconductor wafer toward the counter electrode via the power source. The movement of the electrons generates holes at a portion of the surface of the semiconductor wafer that is lighted by the light. The generated holes flow out into the etchant owing to the voltage applied between the counter electrode and the semiconductor wafer. The surface of the semiconductor wafer is thereby oxidized. The oxidized portion of the semiconductor wafer then dissolves in the etchant. As such, the semiconductor wafer can be etched by repetitive oxidation and dissolution of portion of the semiconductor wafer that is lighted by the light.

### SUMMARY

In the etching device of Japanese Patent Application Publication No. 2017-212262, the counter electrode is disposed on a lateral side of the semiconductor wafer to light an entirety of the surface of the semiconductor wafer by the light. Thus, in the technology of Japanese Patent Application Publication No. 2017-212262, distances from the counter electrode to respective positions on the surface of the semiconductor wafer that is lighted by the light are different. This results in that a flow-out rate of holes from the surface is higher at the positions closer to the counter electrode and is lower at the positions farther from the counter electrode. In other words, a progress rate of the oxidation reaction at the surface is higher at the positions closer to the counter electrode and is lower at the positions farther from the counter electrode. It is therefore difficult to evenly etch the surface of the semiconductor wafer. The present disclosure provides a technology capable of improving evenness of etching on a surface of a semiconductor wafer.

An etching device disclosed herein may be configured to etch a semiconductor wafer by photoelectrochemical etching. The etching device may comprise a reservoir storing an etchant, a support member configured to rotatably support the semiconductor wafer in a state where a first surface of the semiconductor wafer is immersed in the etchant, a light source configured to emit light to the first surface of the semiconductor wafer supported by the support member, a counter electrode disposed in the reservoir, disposed between the support member and the light source, and disposed at a position separated from the first surface of the semiconductor wafer supported by the support member, and a power source configured to apply a voltage between the semiconductor wafer supported by the support member and the counter electrode. When the light source emits light, a lighted area by the light and a shadow of the counter electrode may be projected onto the first surface of the semiconductor wafer supported by the support member, and when the semiconductor wafer is rotated by the support member, at least a part of the first surface may pass both the lighted area and the shadow.

In the above-described etching device, the counter electrode is disposed between the support member and the light source. In other words, the counter electrode is disposed between the first surface of the semiconductor wafer and the light source. Moreover, when the light source emits light in a state where the semiconductor wafer is supported by the support member, the lighted area by the light and the shadow of the counter electrode are projected onto the first surface of the semiconductor wafer. When the semiconductor wafer is rotated, at least a part of the first surface passes a position facing the counter electrode (i.e., the shadow). Due to the arrangement of the counter electrode and the first surface of the semiconductor wafer, the voltage can be applied evenly to an entirety of the part. Moreover, this part also passes the lighted area lighted by the light emitted from the light source. The entirety of the part is therefore lighted by the light. As such, the above-described etching device can apply the voltage evenly to the entirety of the at least part of the first surface of the semiconductor wafer, and further can evenly light the entirety of the at least part of the first surface of the semiconductor wafer. Therefore, the entirety of the part can be evenly etched.

### BRIEF DESCRIPTION OF DRAWINGS

FIG. 1 is a schematic diagram of an etching device 10 of a first embodiment;

FIG. 2 is a plan view of a counter electrode 20 and a semiconductor wafer 12 supported by a support member 16 of the first embodiment;

FIG. 3 is a diagram showing a state where light is emitted to the semiconductor wafer 12 through the counter electrode 20 of the first embodiment;

FIG. 4 is a plan view of a counter electrode 120 and the semiconductor wafer 12 supported by the support member 16 of a second embodiment; and

FIG. 5 is a diagram showing a state where light is emitted to the semiconductor wafer 12 past the counter electrode 120 of the second embodiment.

### DETAILED DESCRIPTION

Representative, non-limiting examples of the present disclosure will now be described in further detail with reference to the attached drawings. This detailed description is merely intended to teach a person of skill in the art further details for practicing preferred aspects of the present teachings and is not intended to limit the scope of the present disclosure. Furthermore, each of the additional features and teachings disclosed below may be utilized separately or in conjunction with other features and teachings to provide improved etching devices, as well as methods for using and manufacturing the same.

Moreover, combinations of features and steps disclosed in the following detailed description may not be necessary to practice the present disclosure in the broadest sense, and are instead taught merely to particularly describe representative examples of the present disclosure. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### First Embodiment

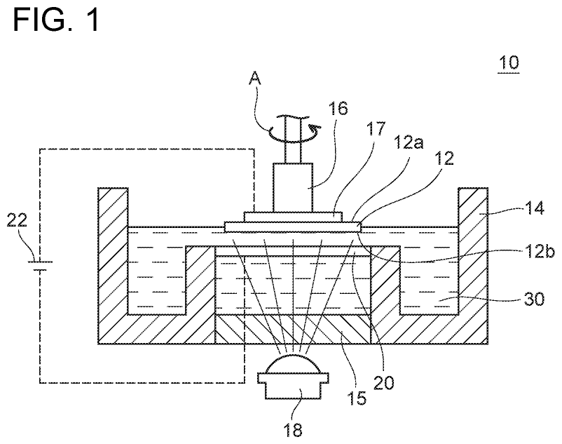

With reference to the drawings, an etching device 10 of a first embodiment will be described. The etching device 10 of the present embodiment is an etching device used for photoelectrochemical etching. As shown in FIG. 1, the etching device 10 includes a reservoir 14, a support member 16, a light source 18, a counter electrode 20, and a power source 22. The reservoir 14 stores an etchant 30. The etchant 30 is a mixed aqueous solution of, for example, hydrofluoric acid and nitric acid. The mixed aqueous solution may further contain a solvent such as alcohols.

The support member 16 is an apparatus configured to support a semiconductor wafer 12. The semiconductor wafer 12 has a disk shape, and includes an upper surface 12a and a lower surface 12b. The semiconductor wafer 12 is constituted of a semiconductor material such as silicon carbide (SiC) or silicon (Si). In the etching device 10 of the present embodiment, the support member 16 supports the semiconductor wafer 12 by suctioning the upper surface 12a of the semiconductor wafer 12. The support member 16 supports the semiconductor wafer 12 in a state where the lower surface 12b of the semiconductor wafer 12 is immersed in the etchant 30. The etching device 10 is configured to etch the lower surface 12b of the semiconductor wafer 12 by photoelectrochemical etching. Moreover, as shown by an arrow A in FIG. 1, the support member 16 rotates the supported semiconductor wafer 12. In the present embodiment, when the support member 16 rotates the supported semiconductor wafer 12, the semiconductor wafer 12 is rotated about a central axis of its disk shape as a rotation axis. The support member 16 is provided with a feeding electrode 17. The feeding electrode 17 is electrically connected to the semiconductor wafer 12 by contacting the upper surface 12a of the semiconductor wafer 12 supported by the support member 16.

The light source 18 is provided below the reservoir 14. The light source 18 is configured to emit light to the lower surface 12b of the semiconductor wafer 12 supported by the support member 16, through sapphire glass 15 provided at a bottom of the reservoir 14. An example of the light source 18 is a light source that emits ultraviolet light and the like, but is not particularly limited thereto.

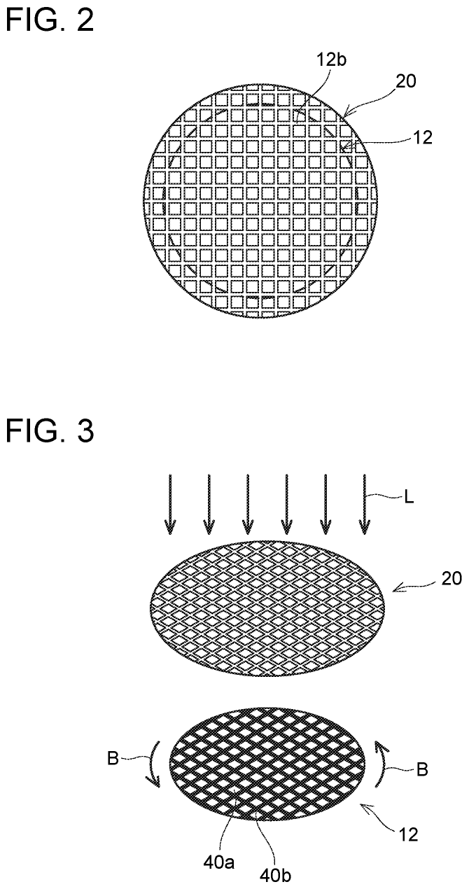

The counter electrode 20 is disposed in the reservoir 14. The counter electrode 20 is immersed in the etchant 30. The counter electrode 20 is disposed between the support member 16 and the light source 18. In other words, the counter electrode 20 is provided at a position facing the lower surface 12b of the semiconductor wafer 12 supported by the support member 16. The counter electrode 20 is disposed at a position separated from the lower surface 12b of the semiconductor wafer 12 supported by the support member 16. The counter electrode 20 is constituted of a material that is superior in electrical conductivity and dissolves sparingly in the etchant 30. The counter electrode 20 is constituted of a metal material such as platinum. As shown in FIG. 2, in a plan view, the counter electrode 20 is configured to have a peripheral edge with a ring shape and to be in a form of mesh inside the peripheral edge. Accordingly, a part of the light emitted from the light source 18 reaches the lower surface 12b of the semiconductor wafer 12 through the mesh of the counter electrode 20. The counter electrode 20 has a larger diameter than the semiconductor wafer 12 does. Wires that constitute the mesh of the counter electrode 20 have a diameter of approximately 0.08 mm, for example, but the diameter is not particularly limited thereto.

The power source 22 is connected to the feeding electrode 17 of the support member 16 and to the counter electrode 20. The power source 22 is configured to apply a DC voltage between the feeding electrode 17 and the counter electrode 20. As shown in FIG. 1, the power source 22 has its positive electrode connected to the feeding electrode 17 (i.e., the supported semiconductor wafer 12), and has its negative electrode connected to the counter electrode 20. As described above, the feeding electrode 17 is electrically connected to the semiconductor wafer 12 supported by the support member 16. Therefore, when the power source 22 applies a DC voltage between the feeding electrode 17 and the counter electrode 20, the DC voltage is applied between the semiconductor wafer 12 supported by the support member 16 and the counter electrode 20.

Next, photoelectrochemical etching of the semiconductor wafer 12 by use of the etching device 10 will be described. First, the etchant 30 is stored in the reservoir 14 in which the counter electrode 20 is disposed. Subsequently, the semiconductor wafer 12 is disposed in the reservoir 14 that stores the etchant 30. Specifically, the semiconductor wafer 12, which is to be processed, is firstly supported by the support member 16. In other words, the semiconductor wafer 12 allows its upper surface 12a to contact the feeding electrode 17 to let the support member 16 support the semiconductor wafer 12. The support member 16 is then disposed such that the lower surface 12b of the semiconductor wafer 12 faces the counter electrode 20 and is opposed to the light source 18. At this time, a position of the support member 16 is adjusted such that the lower surface 12b of the semiconductor wafer 12 is immersed in the etchant 30. At this time, an entirety of the semiconductor wafer 12 may be immersed in the etchant 30. Moreover, the storing of the etchant 30 and the disposing of the semiconductor wafer 12 may be performed in any order, not limited to particular one. After the support member 16 that supports the semiconductor wafer 12 has been disposed at a predetermined position, the etchant 30 may be stored in the reservoir 14.

Next, the supported semiconductor wafer 12 is rotated by the support member 16. The semiconductor wafer 12 is maintained in a state of being rotated at a constant speed at all times, during the photoelectrochemical etching. Then, the power source 22 is turned on to apply a voltage between the semiconductor wafer 12 and the counter electrode 20, and the light source 18 is activated to emit light toward the lower surface 12b of the semiconductor wafer 12. As described above, the light reaches the lower surface 12b of the semiconductor wafer 12 through the counter electrode 20 in the form of mesh. Thus, a part of the light emitted from the light source 18 reaches the lower surface 12b of the semiconductor wafer 12 through spaces of the mesh of the counter electrode 20. Specifically, as shown in FIG. 3, when the light source 18 emits light L, a lighted area 40a by the light L emitted from the light source 18 and a shadow 40b of the counter electrode 20 are projected onto the semiconductor wafer 12. Here, as shown by arrows B in FIG. 3, the semiconductor wafer 12 is rotating at a constant speed. In contrast, the counter electrode 20 is fixed, and hence a projection area onto which the lighted area 40a and the shadow 40b are projected is fixed. Therefore, while the light source 18 emits the light, a substantial entirety of the lower surface 12b of the semiconductor wafer 12 alternately passes the lighted area 40a and the shadow 40b.

As such, in the present embodiment, the etching is performed while the supported semiconductor wafer 12 is rotated. The entirety of the lower surface 12b of the semiconductor wafer 12 thus passes positions facing the counter electrode 20 (i.e., the shadow 40b). Moreover, a distance between the lower surface 12b of the semiconductor wafer 12 and the counter electrode 20 is approximately constant across the entirety of the lower surface 12b of the semiconductor wafer 12. The voltage can therefore be applied evenly to the entirety of the lower surface 12b of the semiconductor wafer 12. Moreover, in the present embodiment, the substantial entirety of the lower surface 12b of the semiconductor wafer 12 also passes the lighted area 40a by the light emitted by the light source 18. Therefore, the substantial entirety of the lower surface 12b of the semiconductor wafer 12 can be evenly lighted by the light.

When the lower surface 12b is lighted by the light, holes and free electrons are generated within the semiconductor wafer 12 in the vicinity of the lower surface 12b. Owing to an influence of the voltage applied between the semiconductor wafer 12 and the counter electrode 20, the free electrons flow to the counter electrode 20 through a wiring and the power source 22, and the holes diffuse from the semiconductor wafer 12 into the etchant 30. The holes that have diffused into the etchant 30 move in the etchant 30 to the counter electrode 20, and are bonded to the free electrons. When the holes diffuse from the semiconductor wafer 12 into the etchant 30, an oxide film (SiO₂) is formed on the lower surface 12b of the semiconductor wafer 12. The formed oxide film dissolves into the etchant 30. As described above, the lower surface 12b of the semiconductor wafer 12 is etched.

In the etching device 10 of the present embodiment, the voltage can be applied evenly to the entirety of the lower surface 12b of the semiconductor wafer 12 and the entirety of the lower surface 12b of the semiconductor wafer 12 can be evenly lighted by the light. Therefore, in the photoelectrochemical etching by use of the etching device 10 of the present embodiment, the etching proceeds at approximately the same speed across the entirety of the lower surface 12b of the semiconductor wafer 12. In other words, the etching can be performed without unevenness across the entirety of the lower surface 12b of the semiconductor wafer 12. Through the above-described steps, the etching on the lower surface 12b of the semiconductor wafer 12 is completed.

### Second Embodiment

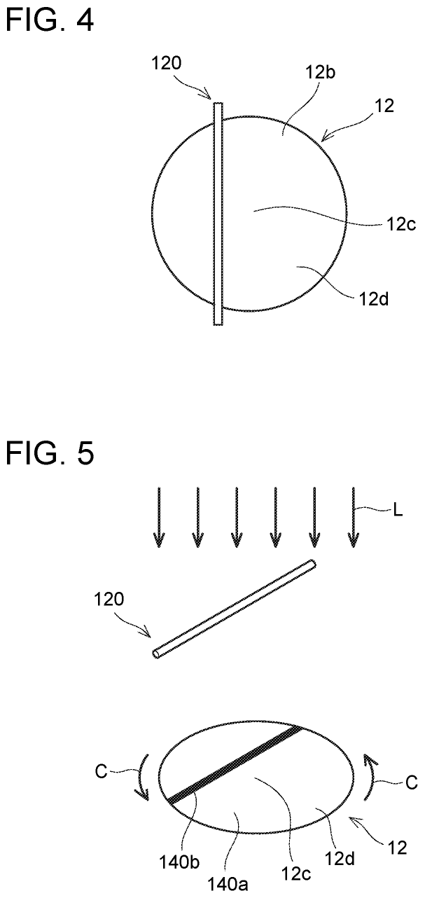

An etching device 100 of a second embodiment has configurations similar to those of the first embodiment, except that a configuration of a counter electrode 120 is different from the counter electrode 20 of the first embodiment. In the second embodiment, as shown in FIG. 4, the counter electrode 120 is configured to be in a form of a rod. The counter electrode 120 is provided at a position displaced from a central portion 12c of the semiconductor wafer 12 supported by the support member 16. In other words, in a plan view of the counter electrode 120 and the semiconductor wafer 12, the counter electrode 120 does not overlap the central portion 12c of the semiconductor wafer 12. The counter electrode 120 is provided at a position facing a peripheral portion 12d of the semiconductor wafer 12 supported by the support member 16. In the plan view of the counter electrode 120 and the semiconductor wafer 12 supported by the support member 16, both ends of the counter electrode 120 are located outside relative to the peripheral edge of the semiconductor wafer 12. A cross section of the counter electrode 120 is not particularly limited. The counter electrode 120 may have a cross section of, for example, a circular shape or a polygonal shape.

In photoelectrochemical etching of the semiconductor wafer 12 by use of the etching device 100, the power source 22 is turned on and the light source 18 is activated while the supported semiconductor wafer 12 is rotated by the support member 16, as in the first embodiment. The light reaches the lower surface 12b of the semiconductor wafer 12 past the counter electrode 120 in the form of a rod. Thus, a part of the light emitted from the light source 18 reaches the lower surface 12b of the semiconductor wafer 12 past the counter electrode 120. Specifically, as shown in FIG. 5, when the light source 18 emits the light L, a lighted area 140a by the light L emitted from the light source 18 and a shadow 140b of the counter electrode 120 are projected onto the lower surface 12b of the semiconductor wafer 12. Since the counter electrode 120 is provided at the position displaced from the central portion 12c of the semiconductor wafer 12, the shadow 140b is projected onto the position displaced from the central portion 12c of the semiconductor wafer 12. At this time, as shown by arrows C in FIG. 5, the semiconductor wafer 12 is rotating at a constant speed. Therefore, while the light source 18 emits the light, the peripheral portion 12d of the semiconductor wafer 12 alternately passes the lighted area 140a and the shadow 140b. In contrast, the central portion 12c of the semiconductor wafer 12 is constantly positioned within the lighted area 140a.

As such, in the present embodiment, the voltage can be applied evenly to the peripheral portion 12d of the lower surface 12b of the semiconductor wafer 12, and the peripheral portion 12d of the lower surface 12b of the semiconductor wafer 12 can be evenly lighted by the light. The etching thus proceeds at approximately the same speed across the entirety of the peripheral portion 12d. Moreover, in the present embodiment, the central portion 12c of the lower surface 12b of the semiconductor wafer 12 can be evenly lighted by the light. The central portion 12c does not pass the shadow 140b, but is disposed at a position relatively close to the counter electrode 120. An appropriate voltage is thus applied also to the central portion 12c. Therefore, the etching proceeds evenly on the central portion 12c as well, at a speed similar to the speed of the etching on the peripheral portion 12d. As such, in the photoelectrochemical etching by use of the etching device 100 of the present embodiment as well, the etching can be performed with high evenness across the entirety of the lower surface 12b of the semiconductor wafer 12.

In the above-described embodiments, the entirety of or a most part of the lower surface 12b of the semiconductor wafer 12 passes both the lighted area by the light and the shadow by rotating the semiconductor wafer 12 in etching the semiconductor wafer 12. However, at least a part of the lower surface 12b of the semiconductor wafer 12 only needs to pass both the lighted area and the shadow when the semiconductor wafer 12 is rotated. Even with such a configuration, evenness of etching on the semiconductor wafer 12 can be improved, because the distance between the semiconductor wafer 12 and the counter electrode become constant compared to a configuration in which the counter electrode is disposed on a lateral side of the semiconductor wafer 12.

Moreover, in the above-mentioned embodiments, the lower surface 12b of the semiconductor wafer 12 is immersed in the etchant 30, and the counter electrodes 20, 120 and the light source 18 are provided below the semiconductor wafer 12. However, the entirety of the semiconductor wafer 12 may be immersed in the etchant 30, and the counter electrodes 20, 120 and the light source 18 may be disposed above the upper surface 12a of the semiconductor wafer 12. In this case, the support member 16 that rotatably supports the semiconductor wafer 12 can be provided in the reservoir 14. According to this configuration, the upper surface 12a of the semiconductor wafer 12 can be etched by emitting light to and applying a voltage to the upper surface 12a.

Some of the features characteristic to the technology disclosed herein will be listed below. It should be noted that the respective technical elements are independent of one another, and are useful solely or in combinations.

In a configuration disclosed herein as an example, when the semiconductor wafer is rotated by the support member, an entirety of the first surface may pass both the lighted area and the shadow.

With such a configuration, the entirety of the first surface of the semiconductor wafer can be lighted by the light and the voltage can be applied thereto. Therefore, the entirety of the first surface of the semiconductor wafer can be substantially evenly etched.

In a configuration disclosed herein as an example, the counter electrode may be in a form of mesh.

With such a configuration, the entirety of the first surface of the semiconductor wafer can be lighted by the light and the voltage can be applied thereto with a simple configuration.

In a configuration disclosed herein as an example, when the semiconductor wafer is rotated by the support member, a peripheral portion of the first surface may pass both the lighted area and the shadow, and a central portion of the first surface may be constantly positioned within the lighted area.

With such a configuration, the entirety of the first surface of the semiconductor wafer can be lighted by the light. Moreover, since the peripheral portion of the first surface passes both the lighted area and the shadow, the distance between the entirety of the first surface and the counter electrode becomes constant, such that evenness of etching on the first surface can be improved.

In a configuration disclosed herein as an example, the counter electrode may be in a form of a rod and face the peripheral portion of the first surface at a position displaced from the central portion of the first surface.

With such a configuration, the counter electrode faces the first surface at the position displaced from the central portion of the first surface, such that the central portion, which serves as a rotation axis of the semiconductor wafer, can be lighted by the light. In other words, it can be prevented that the first surface has an area that is not lighted by the light constantly. Therefore, the entirety of the first surface can be etched.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. An etching device configured to etch a semiconductor wafer by photoelectrochemical etching, the etching device comprising:
a reservoir storing an etchant;
a support member configured to rotatably support the semiconductor wafer in a state where a first surface of the semiconductor wafer is immersed in the etchant;
a light source configured to emit light to the first surface of the semiconductor wafer supported by the support member;
a counter electrode disposed in the reservoir, disposed between the support member and the light source, and disposed at a position separated from the first surface of the semiconductor wafer supported by the support member; and
a power source configured to apply a voltage between the semiconductor wafer supported by the support member and the counter electrode,
wherein
when the light source emits light, a lighted area by the light and a shadow of the counter electrode are projected onto the first surface of the semiconductor wafer supported by the support member, and
when the semiconductor wafer is rotated by the support member, at least a part of the first surface passes both the lighted area and the shadow.

2. The etching device of claim 1, wherein
when the semiconductor wafer is rotated by the support member, an entirety of the first surface passes both the lighted area and the shadow.

3. The etching device of claim 1, wherein
the counter electrode is in a form of mesh.

4. The etching device of claim 1, wherein
when the semiconductor wafer is rotated by the support member, a peripheral portion of the first surface passes both the lighted area and the shadow, and a central portion of the first surface is constantly positioned within the lighted area.

5. The etching device of claim 4, wherein
the counter electrode is in a form of a rod and faces the peripheral portion of the first surface at a position displaced from the central portion of the first surface.
